(19) United States
(12) Patent Application Publication
(10) Pub. No.: US 2007/0252277 A1
(43) Pub. Date: Nov. 1, 2007

(54) SEMICONDUCTOR DEVICES AND FABRICATION METHOD THEREOF

(75) Inventors: Jung-Chih Tsao, Taipei City (TW); Kei-Wei Chen, Yonghe City (TW); Shih-Chieh Chang, Tainan (TW); Yu-Ku Lin, Hsinchu City (TW); Ying-Lang Wang, Lung-Jing Township (TW)

Correspondence Address: Daniel R. McClure;Thomas, Kayden, Horstemeyer & Risley, LLP, Suite 1750, 100 Galleria Parkway, Atlanta, GA, 30339, US

(73) Assignee: Taiwan Semiconductor Manufacturing Co., Ltd., Hsin-Chu (TW)

(21) Appl. No.: 11/380,666

(22) Filed: Apr. 28, 2006

(51) Int. Cl. H01L 23/52; H01L 21/4763

(52) U.S. Cl. 257/751; 438/637; 438/643; 438/648; 257/761; 257/763

(57) ABSTRACT

A semiconductor device. The semiconductor device includes a substrate, a dielectric layer formed thereon, an opening formed in the dielectric layer, a first barrier layer overlying the sidewall of the opening, a second barrier layer overlying the first barrier layer and the bottom of the opening, and a conductive layer filled into the opening. The invention also provides a method of fabricating the semiconductor device.

### BACKGROUND OF THE INVENTION

1. Field of the Invention

The invention relates to a semiconductor device, and in particular to a semiconductor device without micro-trenches and a fabrication method thereof.

2. Description of the Related Art

Typically, interconnect structures in IC (Integrated Circuit) include semiconductor structures such as transistors, capacitors, resistors, and the like, formed on a substrate. One or more conductive layers formed of metal or metal alloy separated by dielectric layers are formed over the semiconductor structures and interconnected thereto. Currently, copper is utilized for metal lines in interconnect structures due to the high conductivity thereof. At the same time, an improved metal line structure such as a dual damascene structure has been developed as it requires fewer fabrication steps.

Fabrication of dual damascene structure involves simultaneous formation of a trench and a via through a dielectric layer. The bottom of the via is a contact area for connecting an underlying metal line or semiconductor structure.

A barrier layer is deposited along a sidewall and bottom of a via and a trench to prevent the diffusion of the compositions of the metal line and plug therein into the neighboring dielectric layer. A thick barrier layer, however, is not an ideal conductor, as it undesirably increases resistance in the resulting interconnect structure.

Referring to FIG. 1A, a substrate 100 with a contact region 105 and a dielectric layer 110 formed thereon is provided. The dielectric layer 110 is then etched to form a dual damascene opening 110a comprising a lower via portion 111 and a wider upper trench portion 112, exposing the contact region 105, wherein the bottoms of the upper portion act as shoulders 113 of the opening 110a. Next, a barrier layer 120 is conformally deposited on the dielectric layer 110 and the surface of the opening 110a. The barrier layer 120, near trench corners 114 and via corners 115, is apparently thinner than a predetermined thickness. The barrier layer 120 is then sputtered utilizing bombardment of inert gas, i.e. argon plasma. The sputtering is not selective, however, and the thinner barrier layer 120 at the opening shoulder is also etched and completely consumed during sputtering etching. Thus, the underlying dielectric layer 110 is etched and recessed, forming undesirable micro-trenches 116 at trench corners 114, as shown in FIG. 1B, seriously affecting electrical performance of devices.

### BRIEF SUMMARY OF THE INVENTION

The invention provides a semiconductor device comprising a substrate, a dielectric layer formed thereon, an opening formed in the dielectric layer, a first barrier layer overlying the sidewall of the opening, a second barrier layer overlying the first barrier layer and the bottom of the opening, and a conductive layer filled into the opening.

The invention provides a semiconductor device comprising a substrate, a dielectric layer formed thereon, an opening comprising a trench and a via connecting thereto formed in the dielectric layer, a first barrier layer overlying the surface of the trench and the sidewall of the via, a second barrier layer overlying the first barrier layer and the bottom of the via, and a conductive layer filled into the opening.

The invention also provides a method of fabricating a semiconductor device, comprising the following steps. A substrate with a dielectric layer formed thereon is provided. An opening is formed in the dielectric layer. A first barrier layer is deposited on the surface of the opening. The first barrier layer is resupttered to remove the portion thereof overlying the opening bottom. A second barrier layer is deposited on the first barrier layer and the bottom of the opening. The second barrier layer is resputtered. A conductive layer is filled into the opening.

The invention further provides a method of fabricating a semiconductor device, comprising the following steps. A substrate with a dielectric layer formed thereon is provided. An opening comprising a trench and a via connecting thereto is formed in the dielectric layer. A first barrier layer is deposited on the surface of the opening. The first barrier layer is resupttered to remove the portion thereof overlying the via bottom. A second barrier layer is deposited on the first barrier layer and the bottom of the via. The second barrier layer is resputtered. A conductive layer is filled into the opening.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIGS. 1A˜1B are cross sections of a conventional method of fabricating a semiconductor device.

FIGS. 2A˜2H are cross sections of a method of fabricating a semiconductor device of an embodiment of the invention.

FIGS. 3A˜3H are cross sections of a method of fabricating a semiconductor device of an embodiment of the invention.

FIGS. 4A˜4J are cross sections of a method of fabricating a semiconductor device of an embodiment of the invention.

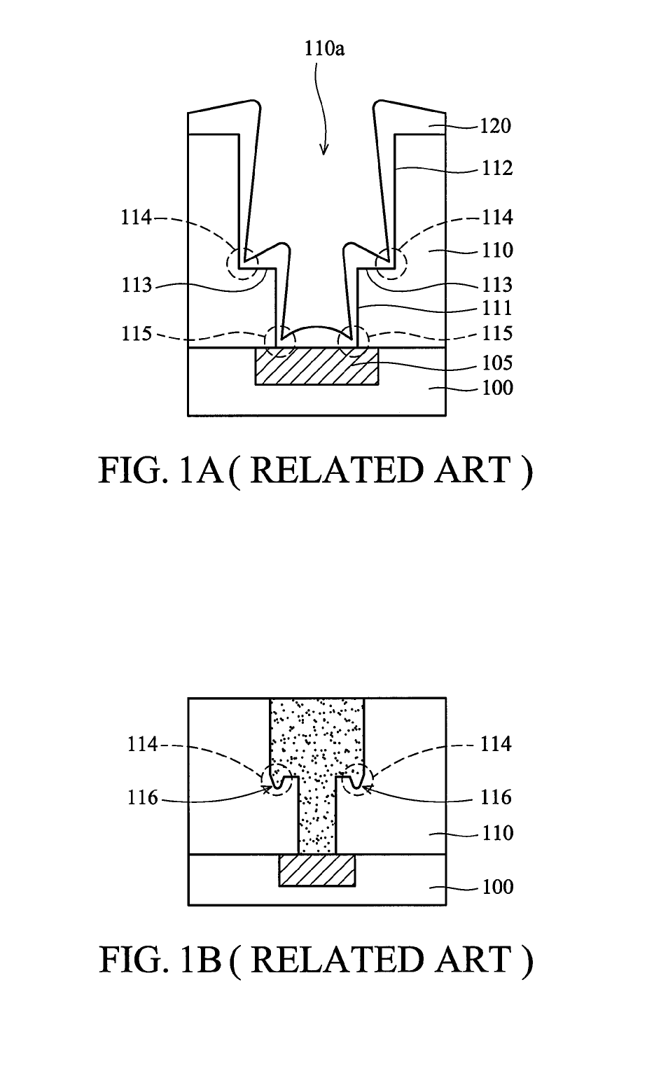

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

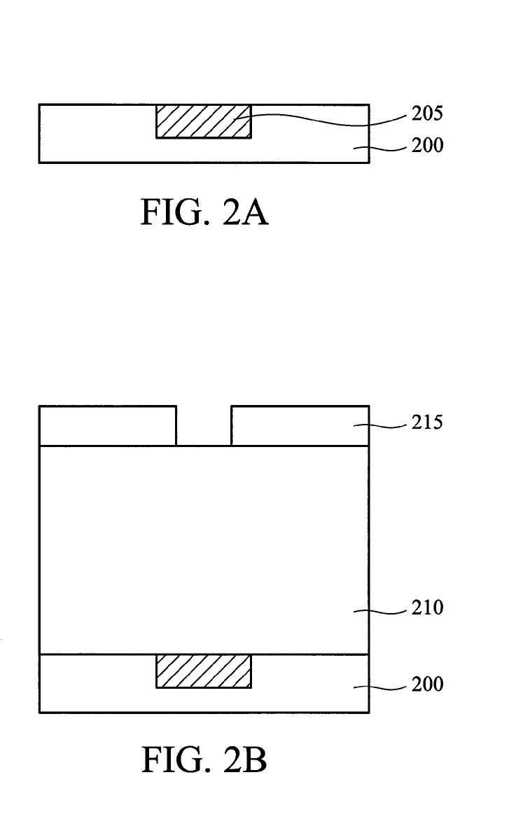

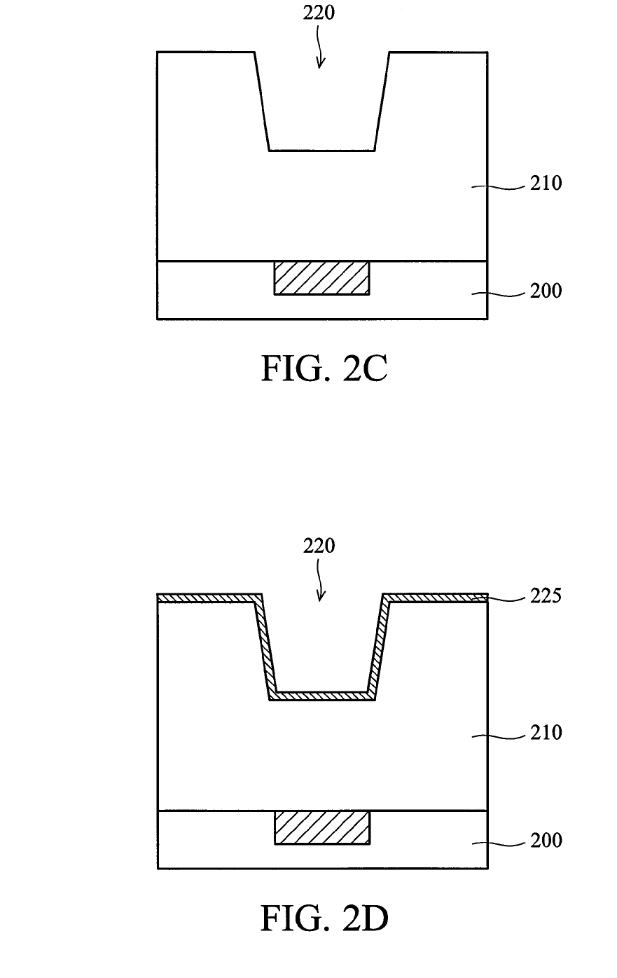

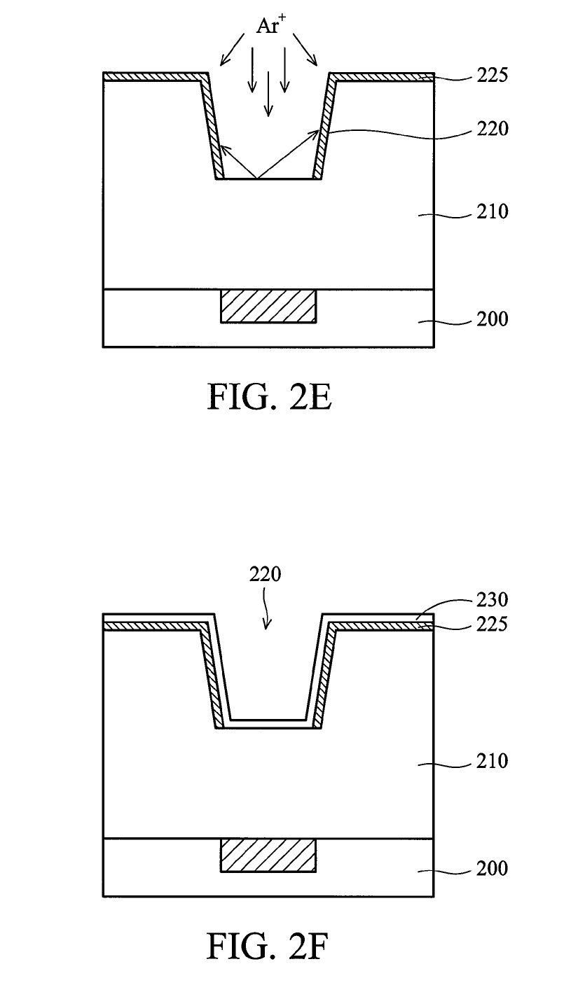

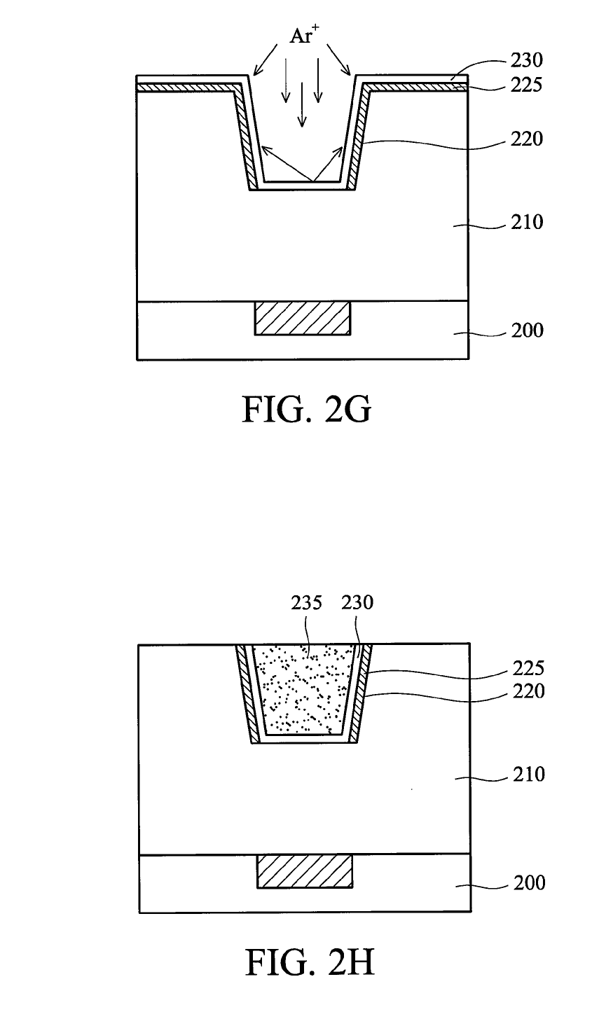

FIGS. 2A˜2H are cross sections of a method of fabricating a semiconductor device according to an embodiment of the invention.

Referring to FIG. 2A, a substrate 200, such as silicon, germanium, silicon germanium, semiconductor compounds, or other known semiconductor materials, is provided. Typically, the substrate 200 comprises active devices such as diodes or transistors or passive devices such as resistors, capacitors, or inductors (not shown). In some cases, the substrate 200 may comprise an exposed contact region 205 such as a copper conductive layer.

A dielectric layer 210 is then formed on the substrate 200, as shown in FIG. 2B. The dielectric layer 210 may be an oxide-based layer such as boron phosphorous silicon glass (BPSG) layer, fluorinated silicate glass (FSG) layer, or other layers formed by chemical vapor deposition (CVD) using tetraethoxysilane (TEOS) as precursor. The dielectric layer 210 may comprise any known low-k material, with dielectric constant less than 4, preferably as great as 3 or less. Next, a patterned photoresist layer 215 is formed on the dielectric layer 210.

Referring to FIG. 2C, the dielectric layer 210 is then anisotropically etched using the patterned photoresist mask 215 to form a trench 220 therein. The anisotropic etching may comprise reactive ion etching (RIE) or plasma etching.

Next, a first barrier layer 225 is conformally formed on the surface of the trench 220 and the dielectric layer 210 by such as physical vapor deposition (PVD), as shown in FIG. 2D. The first barrier layer 225 may comprise tantalum nitride (TaN) or titanium nitride (TiN).

Referring to FIG. 2E, the first barrier layer 225 is then resputtered to remove the portion thereof overlying the trench bottom. Next, a second barrier layer 230, such as tantalum or titanium, is deposited on the first barrier layer 225 and the bottom of the trench 220 by, for example, physical vapor deposition (PVD), as shown in FIG. 2F. The second barrier layer 230 is then resputtered to reduce the thickness thereof at the trench bottom, as shown in FIG. 2G. The first barrier layer 225 and second barrier layer 230 are resputtered using inert gases such as argon gas, at a pressure of about 0.01˜100 mTorr, at a temperature of about −40˜200° C., and with a power of 600˜1000 W.

In the resputtering step, the first barrier layer 225 overlying the trench bottom is completely removed therefrom to the sidewall of the trench 220 by argon ion bombardment. The second barrier layer 230, however, is partially removed, leaving a thin metal barrier layer.

During the foregoing processes, the ratio of the resputter amount to the deposition amount is no greater than 0.6, for example equal to 0.5.

Finally, a conductive layer 235 is filled into the trench 220 and planarized to form a semiconductor structure such as a conductive line, as shown in FIG. 2H.

In a low-aspect-ratio trench, a level barrier layer overlying the bottom thereof can still be formed due to an optimal resputter/deposition amount ratio.

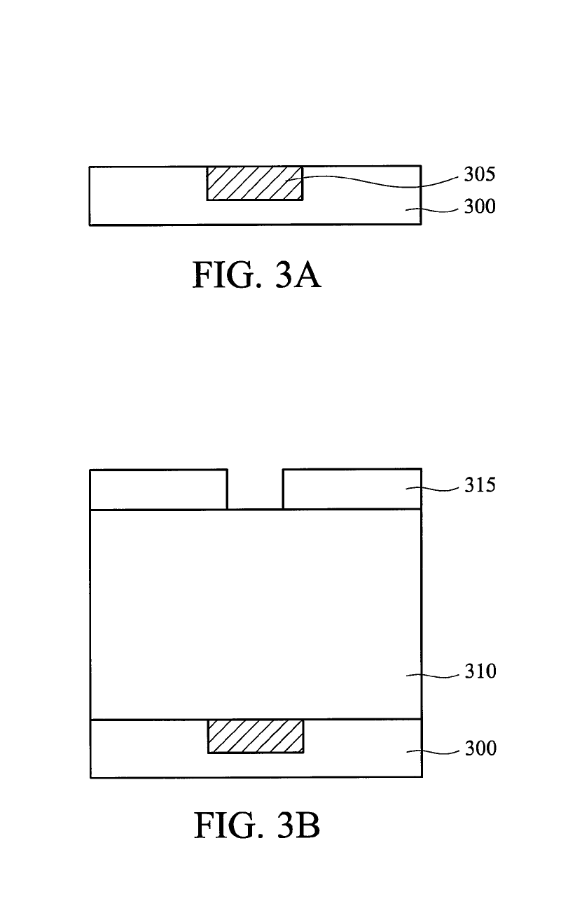

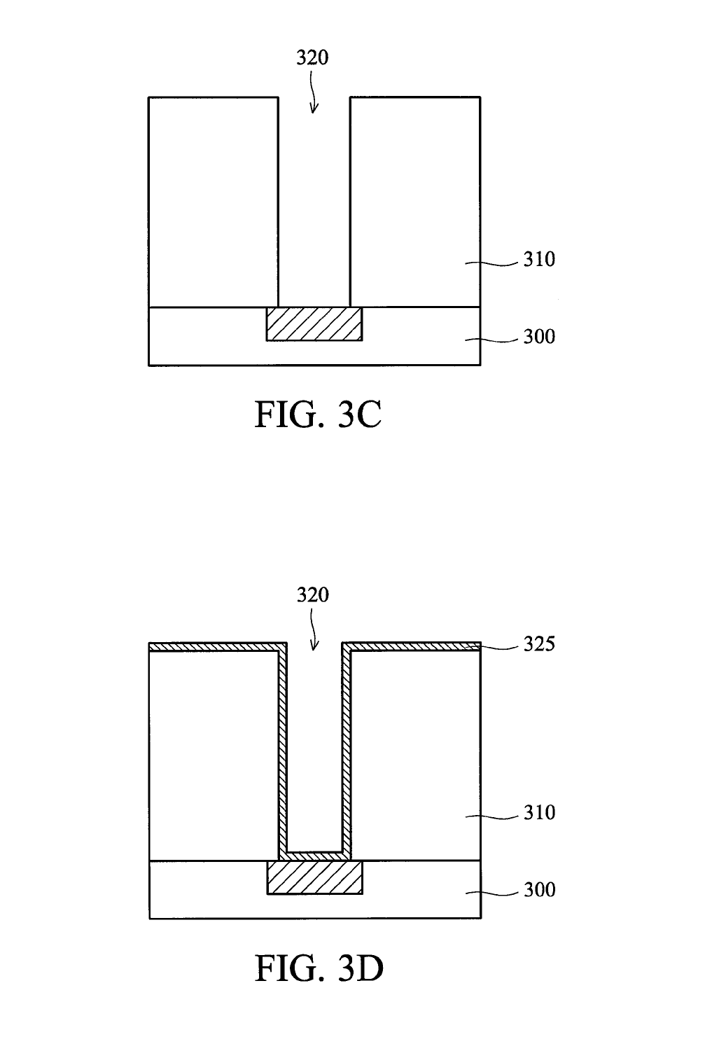

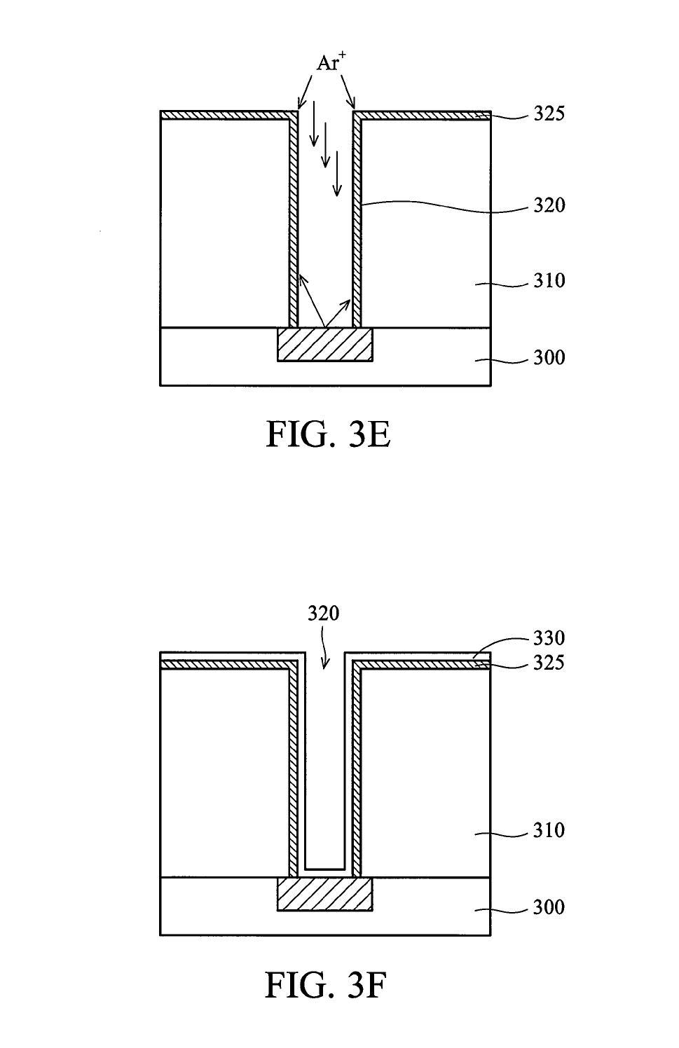

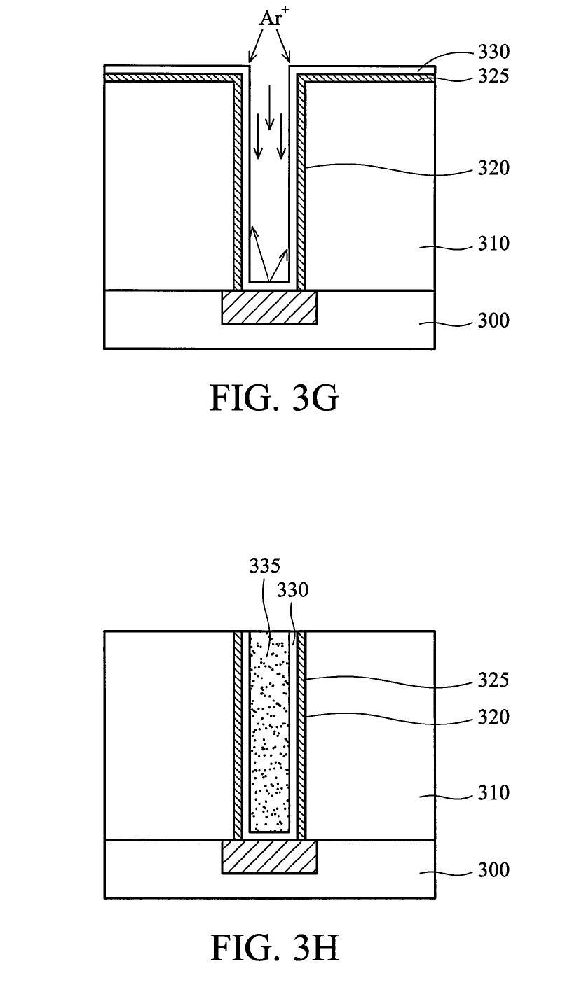

FIGS. 3A˜3H are cross sections of a method of fabricating a semiconductor device according to an embodiment of the invention.

Referring to FIG. 3A, a substrate 300, such as silicon, germanium, silicon germanium, semiconductor compounds, or other known semiconductor materials, is provided. Typically, the substrate 300 comprises active devices such as diodes or transistors or passive devices such as resistors, capacitors, or inductors (not shown). In some cases, the substrate 300 may comprise an exposed contact region 305 such as a copper conductive layer.

A dielectric layer 310 is then formed on the substrate 300, as shown in FIG. 3B. The dielectric layer 310 may be an oxide-based layer such as boron phosphorous silicon glass (BPSG) layer, fluorinated silicate glass (FSG) layer, or other layers formed by chemical vapor deposition (CVD) using tetraethoxysilane (TEOS) as precursor. The dielectric layer 310 may comprise any known low-k material, with dielectric constant less than 4, preferably as great as 3 or less. Next, a patterned photoresist layer 315 is formed on the dielectric layer 310.

Referring to FIG. 3C, the dielectric layer 310 is then anisotropically etched using the patterned photoresist mask 315 to form a via 320 therein, exposing the contact region 305. The anisotropic etching may comprise reactive ion etching (RIE) or plasma etching.

Next, a first barrier layer 325 is conformally formed on the surface of the via 320 and the dielectric layer 310 by such as physical vapor deposition (PVD), as shown in FIG. 3D. The first barrier layer 325 may comprise tantalum nitride (TaN) or titanium nitride (TiN).

Referring to FIG. 3E, the first barrier layer 325 is then resputtered to remove the portion thereof overlying the via bottom. Next, a second barrier layer 330, such as tantalum or titanium, is deposited on the first barrier layer 325 and the bottom of the via 320 by, for example, physical vapor deposition (PVD), as shown in FIG. 3F. The second barrier layer 330 is then resputtered to reduce the thickness thereof at the via bottom, as shown in FIG. 3G. The first barrier layer 325 and second barrier layer 330 are resputtered using inert gases such as argon gas, at a pressure of about 0.01˜100 mTorr, at a temperature of about −40˜200° C., and with a power of 600˜1000 W.

In the resputtering step, the first barrier layer 325 overlying the via bottom is completely removed therefrom to the sidewall of the via 320 by argon ion bombardment. The second barrier layer 330, however, is partially removed, leaving a thin metal barrier layer. The sufficiently thick barrier layer on the via sidewall can effectively reduce metal diffusion, increasing device reliability.

During the foregoing processes, the ratio of the resputter amount to the deposition amount is no greater than 0.6, preferably equal to 0.5.

Finally, a conductive layer 335 is filled into the via 320 and planarized to form a semiconductor structure such as a plug, as shown in FIG. 3H.

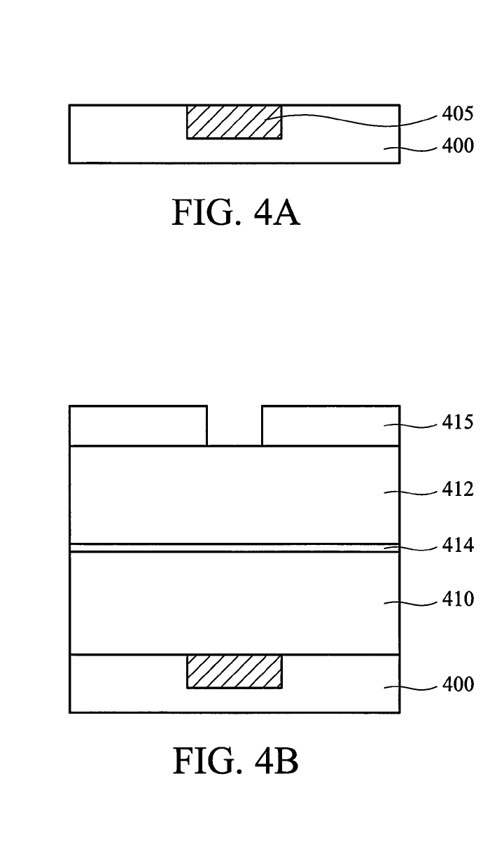

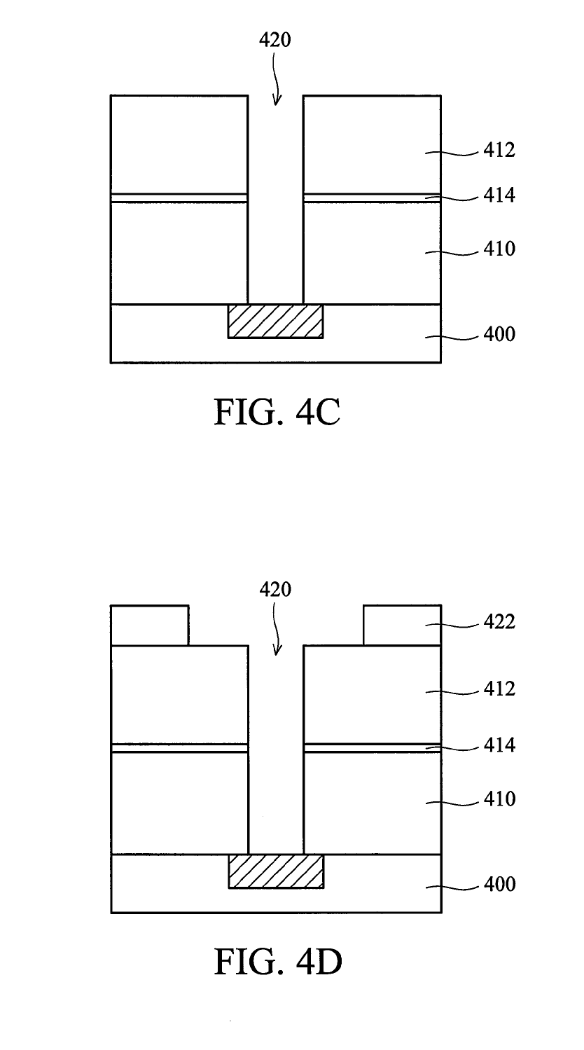

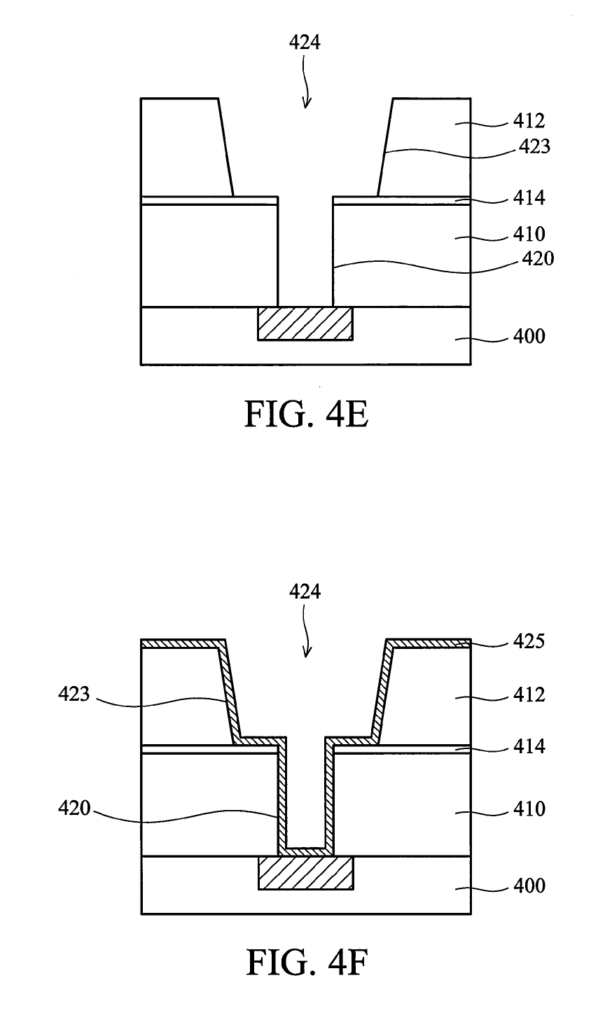

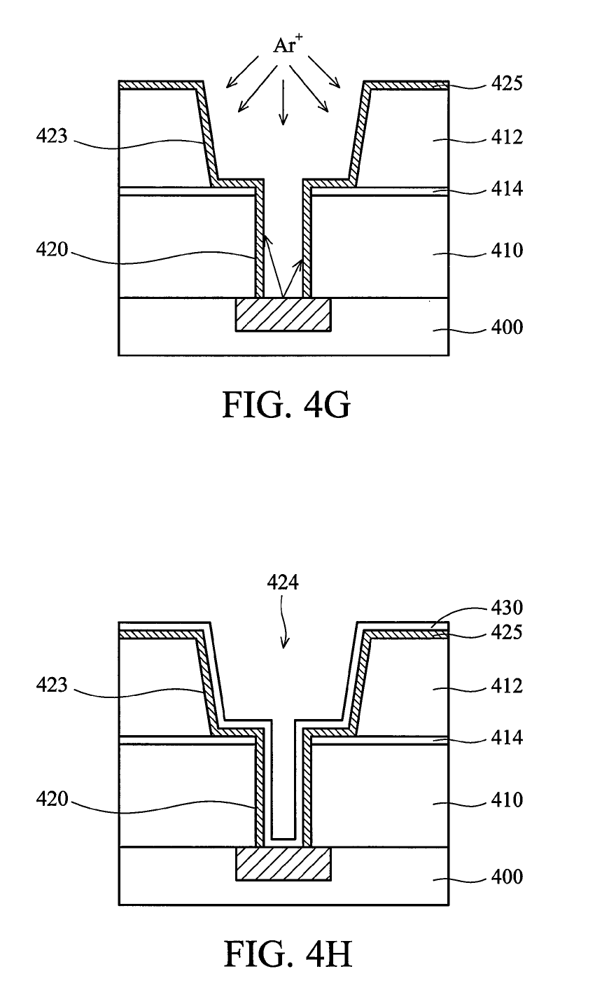

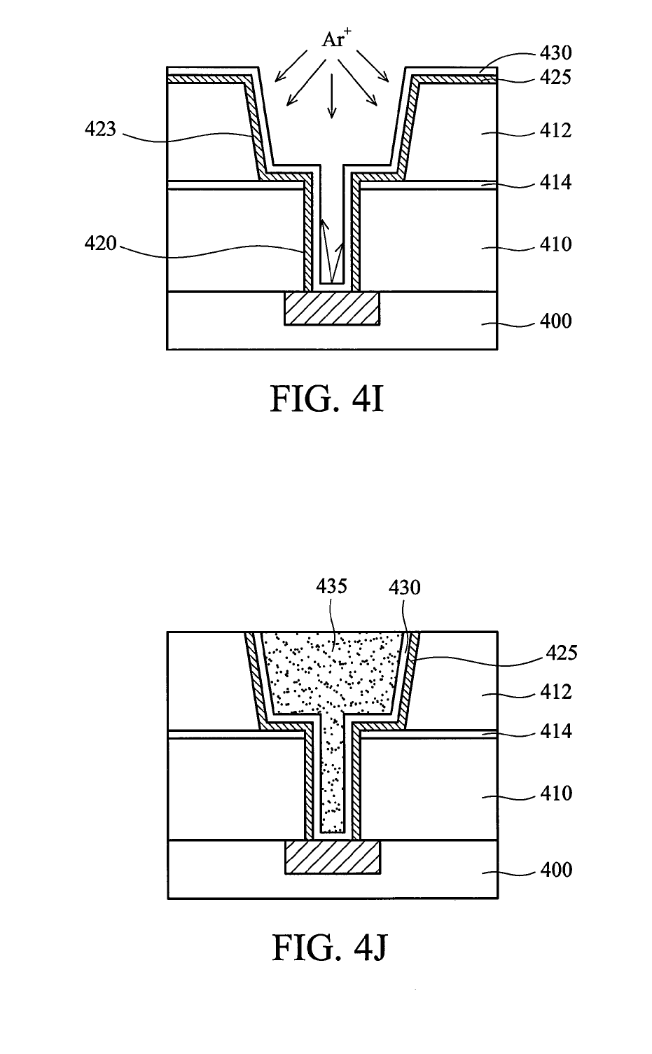

FIGS. 4A˜4H are cross sections of a method of fabricating a semiconductor device according to an embodiment of the invention.

Referring to FIG. 4A, a substrate 400, such as silicon, germanium, silicon germanium, semiconductor compounds, or other known semiconductor materials, is provided. Typically, the substrate 400 comprises active devices such as diodes or transistors or passive devices such as resistors, capacitors, or inductors (not shown). In some cases, the substrate 400 may comprise an exposed contact region 405 such as a copper conductive layer.

A first dielectric layer 410 is then formed on the substrate 400, as shown in FIG. 4B. Next, an etch stop layer 414, such as silicon nitride, is formed on the first dielectric layer 410. A second dielectric layer 412 is then formed on the etch stop layer 414. The first dielectric layer 410 and the second dielectric layer 412 may be an oxide-based layer such as boron phosphorous silicon glass (BPSG) layer, fluorinated silicate glass (FSG) layer, or other layers formed by chemical vapor deposition (CVD) using tetraethoxysilane (TEOS) as precursor. These dielectric layers may comprise any known low-k material, with dielectric constant less than 4, preferably as great as 3 or less. Next, a first patterned photoresist layer 415 is formed on the second dielectric layer 412.

Referring to FIG. 4C, the second dielectric layer 412 and the first dielectric layer 410 are then anisotropically etched using the first patterned photoresist mask 415 to form a via 420 through the first and second dielectric layers, exposing the contact region 405. The anisotropic etching may comprise reactive ion etching (RIE) or plasma etching.

Next, a second patterned photoresist layer 422 is formed on the second dielectric layer 412, as shown in FIG. 4D. The second dielectric layer 412 is then anisotropically etched using the second patterned photoresist mask 422 to form a trench 423, exposing the etch stop layer 414, as shown in FIG. 4E. Thus, an opening 424 comprising the trench 423 and the via 420 is formed. Next, a first barrier layer 425 is conformally formed on the surface of the opening 424 and the second dielectric layer 412 by, for example, physical vapor deposition (PVD), as shown in FIG. 4F. The first barrier layer 425 may comprise tantalum nitride (TaN) or titanium nitride (TiN).

Referring to FIG. 4G, the first barrier layer 425 is then resputtered to remove the portion thereof overlying the via bottom. Next, a second barrier layer 430, such as tantalum or titanium, is deposited on the first barrier layer 425 and the bottom of the via 420 by such as physical vapor deposition (PVD), as shown in FIG. 4H. The second barrier layer 430 is then resputtered to reduce the thickness thereof at the via bottom, as shown in FIG. 4I. The first barrier layer 425 and second barrier layer 430 are resputtered using inert gases such as argon gas, at a pressure of about 0.01˜100 mTorr, at a temperature of about −40˜200° C., and with a power of 600˜1000 W.

In the resputtering step, the first barrier layer 425 overlying the via bottom is completely removed therefrom to the sidewall of the via 420 by argon ion bombardment. The second barrier layer 430, however, is only partially removed, leaving a thin metal barrier layer.

During the foregoing processes, the ratio of the resputter amount to the deposition amount is no greater than 0.6, preferably equal to 0.5.

Finally, a conductive layer 435 is filled into the opening 424 and planarized to form a semiconductor structure such as a dual damascene structure, as shown in FIG. 4J.

The invention provides multiple deposition and resputtering processes and an optimal amount ratio thereof to form an extremely thin metal barrier, thus effectively reducing resistance of the interconnect structure, such as the resistance between the contact region and the inlaid conductive line. Additionally, the barrier layer thickness at the trench corner can also be controlled thereby, avoiding micro-trenches after resputtering.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a dielectric layer overlying the substrate, wherein an opening is formed in the dielectric layer;
a first barrier layer overlying the sidewall of the opening;
a second barrier layer overlying the first barrier layer and the bottom of the opening; and
a conductive layer filled into the opening.

2. The semiconductor device as claimed in claim 1, wherein the dielectric layer comprises low-k materials.

3. The semiconductor device as claimed in claim 1, wherein the opening comprises a trench, a via, or a combination thereof.

4. The semiconductor device as claimed in claim 1, wherein the first barrier layer comprises tantalum nitride or titanium nitride.

5. The semiconductor device as claimed in claim 1, wherein the second barrier layer comprises tantalum or titanium.

6. The semiconductor device as claimed in claim 1, wherein the second barrier layer has a thickness less than 100 Å.

7. A method of fabricating a semiconductor device, comprising:
providing a substrate;
forming a dielectric layer overlying the substrate;
forming an opening in the dielectric layer;
depositing a first barrier layer on the bottom and sidewall of the opening;
resputtering the first barrier layer to remove the first barrier layer from the bottom of the opening;
depositing a second barrier layer on the first barrier layer and the bottom of the opening;
resputtering the second barrier layer; and
filling a conductive layer into the opening.

8. The method of fabricating the semiconductor device as claimed in claim 7, wherein the dielectric layer comprises low-k materials.

9. The method of fabricating the semiconductor device as claimed in claim 7, wherein the opening comprises a trench, a via, or a combination thereof.

10. The method of fabricating the semiconductor device as claimed in claim 7, wherein the first barrier layer comprises tantalum nitride or titanium nitride.

11. The method of fabricating the semiconductor device as claimed in claim 7, wherein the second barrier layer comprises tantalum or titanium.

12. The method of fabricating the semiconductor device as claimed in claim 7, wherein the first and second barrier layers are deposited by physical vapor deposition.

13. The method of fabricating the semiconductor device as claimed in claim 7, wherein the first and second barrier layers are resputtered using inert gas.

14. The method of fabricating the semiconductor device as claimed in claim 13, wherein the inert gas comprises argon gas.

15. The method of fabricating the semiconductor device as claimed in claim 7, wherein the first and second barrier layers are resputtered at a pressure of about 0.01˜100 mTorr, at a temperature of about −40˜200° C., and with a power of 600˜1000 W.

16. The method of fabricating the semiconductor device as claimed in claim 7, wherein the resputter amount and the deposition amount have a ratio no greater than 0.6.

17. The method of fabricating the semiconductor device as claimed in claim 7, wherein the resputter amount and the deposition amount have a ratio of 0.5.
